(19) United States
(12) Patent Application Publication
(10) Pub. No.: US 2024/0234610 A9
(43) Pub. Date: Jul. 11, 2024

(54) A MULTI-JUNCTION SOLAR CELL STRUCTURE GROWN ON BOTH SIDES OF A SUBSTRATE AND A MANUFACTURING METHOD THEREOF

(71) Applicant: Institute of Nuclear Energy Research, Atomic Energy Council, Executive Yuan, R. O. C., Taoyuan (TW)

(72) Inventors: YU-LI TSAI, Taoyuan (TW); Chih-Hung Wu, Taoyuan (TW)

(21) Appl. No.: 18/136,932

(22) Filed: Apr. 20, 2023

(30) Foreign Application Priority Data
Oct. 24, 2022 (TW) 111140257

(51) Int. Cl. H01L 31/0725; H01L 31/0735; H01L 31/18

(52) U.S. Cl. CPC H01L 31/0725; H01L 31/0735; H01L 31/1844

(57) ABSTRACT

A multi junction solar cell structure includes a first sub-cell, a first tunnel diode layer, a second tunnel diode layer, a second sub-cell, a lattice gradient buffer layer and a third sub-cell. The first sub-cell includes a first surface and a second surface opposite to the first surface. The first tunnel diode layer is formed on the first surface of the first sub-cell. The second sub-cell is formed on the first tunnel diode layer. The second tunnel diode layer is formed on the second surface of the first sub-cell. The lattice gradient buffer layer is formed on the second tunnel diode. The third sub-cell is formed on the lattice gradient buffer layer. This disclosure also contains a method for manufacturing the above-mentioned multi-junction solar cell.

### CROSS REFERENCE TO RELATED APPLICATION

All related applications are incorporated by reference. The present application is based on, and claims priority from, Taiwan Application Serial Number 111140257, filed on Oct. 24, 2022, the disclosure of which is hereby incorporated by reference herein in its entirety.

### TECHNICAL FIELD

The present disclosure relates to a solar cell structure, in particular to a III-V multi junction solar cell structure. The present disclosure also relates to a method of manufacturing the multi junction solar cell.

### BACKGROUND

At present, the solar cells for satellite applications adopted by most countries in the world are mainly composed of lattice-matched three-junction GaInP/Ga(In)As/Ge solar cells, and its energy gap combination is 1.9/1.4/0.67 eV, wherein Ga(In)As represents that the indium content is only −1% in the solar cell. The germanium substrate (energy gap value 0.67 eV) is used as the bottom layer sub-cell, and Ga(In)As (energy gap value 1.40 eV) middle layer sub-cell and GaInP (energy gap value 1.9 eV) upper layer sub-cell are sequentially grown on it. Each of the sub-cell is composed of four thin film layers including window layer, emitter layer, base layer, and back surface field layer. Also, there is a tunnel diode between the bottom and middle sub-cells, and between the middle and upper sub-cells to electrically connect the three sub-cells in series. In addition, there is a highly doped contact layer on the upper and lower surfaces of the battery. Since this structure design is a well-known technique for one of ordinary skill in the art, the technical details such as material, doping concentration, and film thickness of each layer will not be repeated herein. The GaInP upper layer sub-cell is responsible for absorbing the solar spectrum band with energy above 1.9 eV, and the Ga(In)As middle layer sub-cell and the Ge bottom layer sub-cell are responsible for absorbing the solar spectrum band with energy above 1.4˜1.9 eV and 0.67˜1.4 eV, respectively. The AM0 practical conversion efficiency of this lattice-matched triple-junction solar cell can reach −30%. However, for the solar spectrum AM0, this energy gap combination is not optimal, because the value of the energy gap of the germanium substrate is too low. Although the Ge bottom sub-cell can generate excessively higher current density than the other two sub-cells, it cannot contribute additional current to them since the electrical connection is in series. The Ge bottom sub-cell can only contribute a slight open circuit voltage value, and does not contribute much to the conversion efficiency of the overall triple-junction cell.

It has been reported that the theoretical conversion efficiency of AM0 of the triple-junction solar cell of GaInP (1.9 eV)/Ga(In)As (1.4 eV)/bottom sub-cell (1.0 eV) can reach as high as 38% if the Ge bottom sub-cell is using a material with an energy gap of 1.0 eV. Currently, there are two materials that can meet the requirement of an energy gap of 1.0 eV, namely dilute nitrogen arsenide GaInNAs (J. F. Geisz et al., AIP Conference Proceedings 462, 372-377 (1999)) and indium gallium arsenide In_{0.3}Ga_{0.7}As with 30% indium content (J. F. Geisz et al., Appl. Phys. Lett. 91, 023502 (2007)). GaInNAs has the advantage that its lattice constant matches with that of the germanium substrate, so it is possible to grow multi junction GaInP/Ga(In)As/GaInNAs/Ge solar cells using the upright epitaxy method disclosed in previous patents (CN104465846A, CN105826420A). However, it has been reported that due to the poor crystallization quality of GaInNAs materials and the high intrinsic defect density, the overall solar cell performance is not as good as expected, and there is still considerable room for improvement in the future. In contrast, the solution of using indium gallium arsenide In_{0.3}Ga_{0.7}As with 30% indium content to make multi junction solar cells seems to be more successful in practice, and it is the mainstream technology adopted by many international manufacturers. However, since the lattice constant of In_{0.3}Ga_{0.7}As does not match with that of the germanium substrate, the international manufacturers adopt the inverted metamorphic (IMM) growth method disclosed in the previous patents (U.S. Pat. Nos. 8,536,446B2, 8,895,342B2). Initially, grow a GaInP nucleation layer on the germanium substrate (if the gallium arsenide substrate is used, it is not necessary to grow this layer), then sequentially grow a GaAs buffer layer, a GaInP etch stop layer, the first highly doped contact layer, a GaInP upper layer sub-cell, the first tunnel diode, a Ga(In)As middle layer sub-cell, the second tunnel diode, a graded buffer layer, a In_{0.3}Ga_{0.7}As bottom layer sub-cell, and the second highly doped contact layer. Since the IMM epitaxy method makes the cell structure grow upside down, the original epitaxy substrate must be ground/etched and removed in conjunction with the device process method, and transfer the multi junction solar cell thin film structure to a carrier. Although IMM technology can realize satellite solar cells with higher conversion efficiency, this technology involves the removal of the original epitaxial substrate and the transfer of the thin film structure to the carrier. The manufacturing process is not only complicated and time-consuming, but also prone to film stress and even film damage problems. It is difficult for IMM method to maintain the process yield; and it is necessary to develop another innovative and simple process technology to solve the aforementioned problems.

It has been reported that it may be an effective and feasible solution to perform epitaxial growth of multi junction solar cells on the upper and lower surfaces of the InP substrate (or GaAs substrate). For example, as disclosed in the previous patent (CN102412337A), an InP substrate is used to make a four-junction solar cell (energy gap combination 1.9/1.35/1.0/0.7 eV) and the substrate itself is used as the light-absorbing base layer. First, an InP emitter layer and an AlInP window layer are sequentially grown on the first surface of the InP substrate to form an InP (1.35 eV) upper layer sub-cell. Afterwards, the first tunneling diode, a graded buffer layer, an InAlAs (˜1.9 eV) top layer sub-cell, and the first highly doped contact layer are grown sequentially. Then, take out and turn over the wafer, so that a AlInP back surface field layer, the second tunnel diode layer, an InGaAsP (1.0 eV) middle layer sub-cell, the third tunnel diode layer, an In_{0.5}Ga_{0.5}As (0.7 eV) bottom layer sub-cell, and the second highly doped contact layer can sequentially grow on the second surface of the InP substrate, and finally a four-junction solar cell with a upright structure (compared to IMM technology) is realized. The advantage of the four-junction structure obtained by the substrate double-sided growth technology is that only one graded buffer layer is involved, and only the InAlAs top layer sub-cell will have dislocation defects, and the remaining three sub-cells are all lattice-matched and a good epitaxial quality can be assured. In addition, since the substrate double-sided growth technology does not involve the removal of the original epitaxial substrate and the transfer of the thin film structure to the carrier, the device manufacturing process is relatively simple and can maintain a better process yield.

An additional example as disclosed in the previous patent (CN104465843A), a GaAs substrate is used to make a four-junction solar cell (energy gap combination 1.9/1.4/1.0/0.7 eV) and the substrate itself is not used as a light-absorbing base layer. At first, the first GaAs buffer layer is grown on the first surface of the substrate, and then the first tunneling diode layer, a GaInNAs (1.0 eV) middle layer sub-cell, the second tunnel diode layer, a GaAs (1.4 eV) upper layer sub-cell, the third tunnel diode layer, a GaInP (1.9 eV) top layer sub-cell, and the first highly doped contact layer are grown sequentially. Afterwards, take out and turn over the wafer, so that the second GaAs buffer layer, a graded buffer layer, a InGaAs (0.7 eV) bottom layer sub-cell, and the second highly doped contact layer can grow on the second surface of the GaAs substrate sequentially, and finally a four-junction solar cell with a upright structure is formed. Similarly, the advantage of the four-junction structure obtained by the substrate double-sided growth technology is that only one graded buffer layer is involved, and only the InGaAs bottom layer sub-cell will have dislocation defects, and the remaining three sub-cells are all lattice-matched and a good epitaxy quality can be assured. In addition, since the substrate double-sided growth technology does not involve the removal of the original epitaxial substrate and the transfer of the thin film structure to the carrier, the device manufacturing process is relatively simple and can maintain a better process yield. However, this structure suffers from two material drawbacks. First of all, although the GaInNAs middle layer sub-cell is lattice-matched, which can effectively avoid the generation of dislocation effects, the intrinsic carrier concentration is too high, which makes the lifetime of the minority carrier too short, and consequently resulting in reducing the overall conversion efficiency. The second problem is, when using InGaAs with an indium content of more than 50% to as the bottom sub-cell with an energy gap of 0.7 eV, there may have phase separation concerns, resulting in a significant defect density inside the InGaAs material. This will also shorten the lifetime of minority carriers and reduce the overall conversion efficiency.

Taking another example disclosed in the previous patent (CN 109148622A), in which a GaAs substrate is used to make a triple-junction solar cell (energy gap combination 1.9/1.4/1.0 eV) and the substrate itself is not used as the light-absorbing base layer. At first, the first GaAs buffer layer is grown on the first surface of the substrate, following by the subsequent growth of then the first tunnel diode layer, a GaAs (1.4 eV) middle layer sub-cell, the second tunnel diode layer, a GaInP (1.9 eV) upper layer sub-cell, and the first highly doped contact layer. Afterwards, take out and turned over the wafer, so that the second GaAs buffer layer, a GaInNAs (1.0 eV) bottom layer sub-cell, and the second highly doped contact layer can sequentially grow on the second surface of the GaAs, and eventually a triple-junction solar cell with upright structure is formed. Similarly, the advantage of the triple-junction structure obtained by the substrate double-sided growth technology is well lattice-matching, and does not involve the removal of the original epitaxial substrate and the transfer of the thin film structure to the carrier, thus the device manufacturing process is relatively simple and can maintain a better process yield. However, this patented technology still faces the disadvantage that the intrinsic carrier concentration of GaInNAs is too high, which makes the lifetime of the minority carrier too short, and there is still room for improvement in conversion efficiency.

To solve the problem of poor crystallization quality when using dilute nitrogen arsenide GaInNAs as the material to make the sub-cell with an energy gap of 1.0 eV and the complicate, time-consuming, and low-yield component manufacturing problems derived from IMM technology as described in the above-mentioned prior art, the inventor of the instant disclosure applies the substrate double-sided growth technology on a double-sided polished GaAs substrate. At first, sequentially grow a GaAs (1.4 eV) middle layer first sub-cell and a GaInP (1.9 eV) upper layer second sub-cell on the first surface of the substrate. Then, grow an InGaAs bottom layer third sub-cell on the second surface of the substrate (when the indium content is 30%, that is, In_{0.3}Ga_{0.7}As, the energy gap is about 1.0 eV). Finally, a triple-junction solar cell with a upright structure is obtained. Since this forward triple-junction solar cell just involves one graded buffer layer, only the InGaAs bottom layer third sub-cell will have dislocation defects. Therefore, the remaining two sub-cells are lattice-matched, and a good epitaxy quality can be assured. In addition, the instant disclosure does not involve the removal of the original epitaxial substrate and the transfer of the thin film structure to the carrier, so the device manufacturing process is relatively simple and can maintain a better process yield.

The instant disclosure is not limited to triple-junction solar cells, and can be extended to multi junction solar cells.

### SUMMARY

The instant disclosure provides a multi junction solar cell structure, which includes a first sub-cell, a first tunnel diode layer, a second sub-cell, a second tunnel diode layer and a graded buffer layer. The first sub-cell has a first surface and a second surface opposite thereto. The first tunnel diode layer is disposed on the first surface of the first sub-cell. The second sub-cell is disposed on the first tunnel diode layer. The second tunnel diode layer is disposed on the second surface of the first sub-cell. The graded buffer layer is disposed on the second tunnel diode layer. The third sub-cell disposed on the graded buffer layer.

In one embodiment of the instant disclosure, the first sub-cell of the above-mentioned multi junction solar cell structure includes a double-sided polished p-type GaAs substrate, a first buffer layer, a first emitter layer, a first window layer and a second buffer layer and a first back surface field layer. The double-sided polished p-type GaAs substrate is used as a light-absorbing base layer, which has a first surface and a second surface opposite thereto. The first buffer layer is disposed on the first surface of the substrate. The first emitter layer is disposed on the first buffer layer. The first window layer is disposed on the first emitter layer. The first window layer is adjacent to the first tunnel diode layer. The second buffer layer is disposed on the second surface of the substrate. The first back surface field layer is made of p-type GaInP or p-type AlGaAs, and disposed on the second buffer layer. The first back surface field layer is adjacent to the second tunnel diode layer.

In one embodiment of the instant disclosure, the second sub-cell of the above-mentioned multi junction solar cell structure includes a second back surface field layer, a second base layer, a second emitter layer and a first contact layer. The second back surface field layer is made of p-type AlGaInP, which has a first surface and a second surface opposite thereto. The second surface of the second back surface field layer is adjacent to the first tunnel diode layer. The second base layer is disposed on the first surface of the second back surface field layer. The second emitter layer is disposed on the second base layer. The second window layer is disposed on the second emitter layer. The first contact layer is disposed on the second window layer.

In one embodiment of the instant disclosure, the third sub-cell of the above-mentioned multi junction solar cell structure includes a third window layer, a third emitter layer, a third base layer and a third back surface field layer. The third window layer has a first surface and a second surface opposite thereto. The first surface of the third window layer is adjacent to the graded buffer layer. The third emitter layer is disposed on the second surface of the third window layer. The third base layer is disposed on the third emitter layer. The third back surface field layer is disposed on the third base layer. The second contact layer is disposed on the third back surface field layer.

In one embodiment of the instant disclosure, the first tunnel diode layer of the above-mentioned multi junction solar cell structure further includes a p+-type first tunnel diode layer and an n+-type first tunnel diode layer. The p+-type first tunnel diode layer is made of p+ type AlGaAs. The n+-type first tunnel diode layer is made of n+-type GaInP. The p+-type first tunnel diode layer is adjacent to the second back surface field layer of the second sub-cell, and the n+-type first tunnel diode layer is adjacent to the first window layer of the first sub-cell.

In one embodiment of the instant disclosure, the second tunnel diode layer of the above-mentioned multi junction solar cell structure further includes a p+-type second tunnel diode layer and n+-type second tunnel diode layer. The p+-type second tunnel diode layer is made of p+-type AlGaAs or p+-type GaAs. The n+-type second tunnel diode layer is made of n+-type GaInP or n+-type GaAs. The p+-type second tunnel diode layer is adjacent to the first back surface field layer of the first sub-cell.

In one embodiment of the instant disclosure, the material of the first emitter layer of the above-mentioned multi junction solar cell structure is n-type GaAs or n-type GaInP. When the material of the first emitter layer is n-type GaAs, the material of the first window layer is n-type GaInP. In another embodiment, when the material of the first emitter layer is n-type GaInP, the material of the first window layer is n-type GaInP with 1-3 times higher doping concentration than that of the first emitter layer, or n-type AlInP.

In one embodiment of the instant disclosure, the material of the graded buffer layer of the above-mentioned multi junction solar cell structure can be n-type GaInP or n-type AlInAs. The change of the ratio of its composition elements along the thickness direction can be linear gradient, stepped gradient, or a combination of the two.

In one embodiment of the instant disclosure, the material of the third emitter layer of the above-mentioned multi junction solar cell structure is n-type InGaAs, and the indium content thereof is between 20-40%. The material of the third base layer is p-type InGaAs, and the indium content thereof is between 20-40%.

The instant disclosure further provides another multi junction solar cell structure, which includes a double-sided polished n-type GaAs substrate, a first buffer layer, a first tunnel diode layer, a first sub-cell, a second tunnel diode layer and a second sub-cell and a second buffer layer and a graded buffer layer. The double-sided polished n-type GaAs substrate has a first surface and a second surface opposite thereto. The first buffer layer is disposed on the first surface of the n-type GaAs substrate. The first tunnel diode layer is disposed on the first buffer layer. The first sub-cell is disposed on the first tunnel diode layer. The second tunnel diode layer is disposed on the first sub-cell. The second sub-cell is disposed on the second tunnel diode layer. The second buffer layer is disposed on the second surface of the n-type GaAs substrate. The graded buffer layer is disposed on the second buffer layer. The third sub-cell is disposed on the graded buffer layer.

In one embodiment of the instant disclosure, the first sub-cell of the above-mentioned multi junction solar cell structure includes a first back surface field layer, a first base layer, a first emitter layer and a first window layer. The first back surface field layer is made of p-type GaInP or p-type AlGaAs, which has a first surface and a second surface opposite thereto. The second surface of the first back surface field layer is adjacent to the first tunnel diode layer. The first base layer is disposed on the first surface of the first back surface field layer. The first emitter layer is disposed on the first base layer. The first window layer is disposed on the first emitter layer and is adjacent to the second tunnel diode layer.

In one embodiment of the instant disclosure, the second sub-cell of the above-mentioned multi junction solar cell structure includes a second back surface field layer, a second base layer, a second emitter layer and a first contact layer. The second back surface field layer is made of p-type AlGaInP, which has a first surface and a second surface opposite thereto. The second surface of the second back surface field layer is adjacent to the second tunnel diode layer. The second base layer is disposed on the first surface of the second back surface field layer. The second emitter layer is disposed on the second base layer. The second window layer is disposed on the second emitter layer. The first contact layer is disposed on the second window layer.

In one embodiment of the instant disclosure, the third sub-cell of the above-mentioned multi junction solar cell structure includes a third window layer, a third emitter layer, a third base layer and a third back surface field layer. The third window layer has a first surface and a second surface opposite thereto. The first surface is adjacent to the graded buffer layer. The third emitter layer is disposed on the second surface of the third window layer. The third base layer is disposed on the third emitter layer. The third back surface field layer is disposed on the third base layer. The second contact layer is disposed on the third back surface field layer.

In one embodiment of the instant disclosure, the first tunnel diode layer of the above-mentioned multi junction solar cell structure further includes a p+-type first tunnel diode layer and an n+-type first tunnel diode layer. The p+-type first tunnel diode layer is made of p+-type AlGaAs or p+-type GaAs. The n+-type first tunnel diode layer is made of n+-type GaInP or n+-type GaAs. The p+-type first tunnel diode layer is adjacent to the second surface of the first back surface field layer of the first sub-cell, and the n+-type first tunnel diode layer is adjacent to the first buffer layer.

In one embodiment of the instant disclosure, the material of the first emitter layer of the above-mentioned multi junction solar cell structure is n-type GaAs or n-type GaInP. When the first emitter layer is made of n-type GaAs, the material of the first window layer is n-type GaInP. In another embodiment, when the material of the first emitter layer is n-type GaInP, the material of the first window layer is the n-type GaInP with 1-3 time higher doping concentration than that of the first emitter layer, or n-type AlInP.

In one embodiment of the instant disclosure, the material layer of the graded buffer layer of the above-mentioned multi junction solar cell structure is n-type GaInP or n-type AlInAs. The change of the ratio of its composition elements along the thickness direction can be linear gradient, stepped gradient, or a combination of the two.

In one embodiment of the instant disclosure, the material of the third emitter layer of the above-mentioned multi junction solar cell structure is n-type InGaAs, and the indium content thereof is between 20-40%. The material of the third base layer is p-type InGaAs, and the indium content thereof is between 20-40%.

The instant disclosure also provides a method for manufacturing a multi junction solar cell with the above-mentioned structure, including the following steps:
a. Providing a multi junction solar cell epi wafer including the structure shown in FIG. 1 or FIG. 2;
b. Coating a photoresist protective layer on the surface of the second contact layer of the third sub-cell of the epi wafer;
c. Removing the cover layer and the etch stop layer sequentially by wet etching;
d. Removing the photoresist protective layer;
e. Fabricating a patterned metal upper electrode on the surface of the first contact layer by a standard lithography process, and then adopting rapid thermal annealing to form a low-resistance ohmic contact;
f. Fabricating a lower metal electrode on the surface of the second contact layer by standard lithography process, and then adopting rapid thermal annealing to form a low-resistance ohmic contact;
g. Using a cutting machine or other mechanical means to form a plurality of cutting lines with a certain depth on the surface of the first contact layer, so as to preform a plurality of solar cells that are not fully electrically independent;
h. Applying wet etching and selecting an appropriate etching solution, the first contact layer is partially removed, and eventually the first contact layer is completely removed in the area not covered by the metal upper electrode to expose the window layer beneath, while the area covered by the metal upper electrode is still completely present. During the wet etching process, the lattice damage layer around the cutting line can be removed simultaneously;
i. Forming an anti-reflection film on the surface of the first contact layer by using an electron gun evaporation machine or other evaporation equipment;
j. Using a standard lithography process, partially remove the anti-reflection film above the patterned metal upper electrode on the surface of the first contact layer, and the area of the removed anti-reflection film is slightly larger than the electrode pin;
k. Cutting completely along a plurality of cutting lines of a certain depth pre-formed on the surface of the first contact layer by a cutting machine or a laser cutting or other mechanical means to form a plurality of completely electrically independent solar cells.

After completely cutting the epi wafer by using the above process, a plurality of electrically independent solar cells are obtained.

### BRIEF DESCRIPTION OF THE DRAWINGS

The present disclosure will become more fully understood from the detailed description given herein below and the accompanying drawings which are given by way of illustration only, and thus are not limitative of the present disclosure and wherein:

FIG. 1 is a structural diagram of a multi junction solar cell according to an embodiment of the instant disclosure.

FIG. 2 is a structural diagram of a multi junction solar cell according to another embodiment of the instant disclosure.

FIG. 3 is a flowchart of a manufacturing method of a multi junction solar cell according to an embodiment of the instant disclosure.

### DETAILED DESCRIPTION

Exemplary embodiments of the multi junction solar cell and its manufacturing method of the instant disclosure will be described below with reference to the accompanying drawings. To clearly and fully convey the scope of the instant invention, the components in the drawings may be presented exaggeratedly or reduced in size or proportion, and the same components in the embodiments will be described with the same symbols.

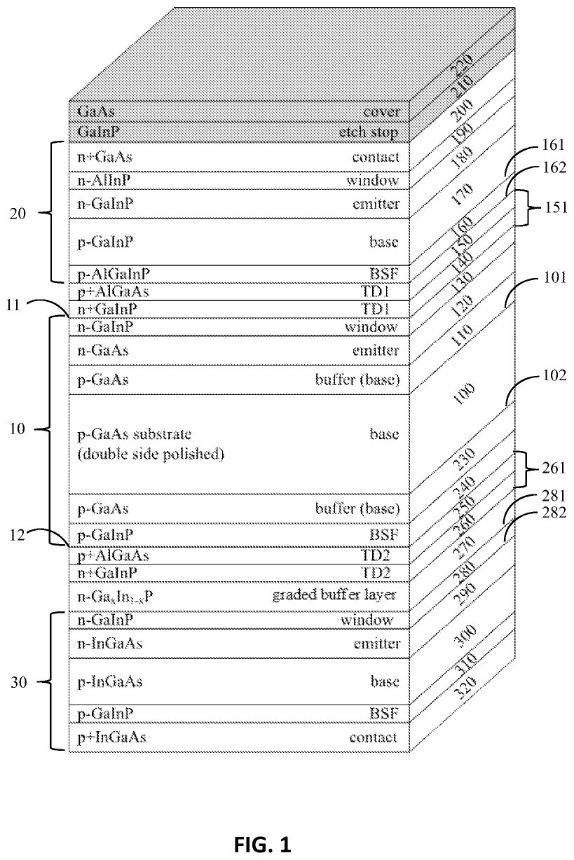

Please refer to FIG. 1, which is a structural diagram of a multi junction solar cell according to an embodiment of the instant disclosure. Herein, the implementation of the instant disclosure will be described in detail according to the structural diagram. The substrate used in this embodiment is a double-sided polished p-type GaAs substrate 100, the thickness of which is not more than 200 microns, and in this embodiment, the double-sided polished p-type GaAs substrate 100 itself also serves as the light-absorbing base layer.

At first, a first buffer layer 110 is grown on the first surface 101 of the GaAs substrate 100. The first buffer layer 110 also serves as a part of the first base layer. The material of the first buffer layer 110 is p-type GaAs, having an energy gap value about 1.4 eV. If the original p-type doping concentration of the substrate 100 is higher than 1×10¹⁸ cm⁻³, the p-type doping concentration of the first buffer layer 110 should be lower than 1×10¹⁸ cm⁻³. In another embodiment, the p-type doping concentration of the first buffer layer 110 is between 1×10¹⁶ cm⁻³ and 1×10¹⁸ cm⁻³.

Above the first buffer layer 110 is the first emitter layer 120 made of homojunction n-type GaAs, with an n-type doping concentration between 5×10¹⁷ cm⁻³ and 5×10¹⁸ cm⁻³. The material of the first emitter layer 120 can also be a lattice-matched heterojunction n-type GaInP, and the n-type doping concentration is between 5×10¹⁷ cm⁻³ and 5×10¹⁸ cm⁻³. In another embodiment, between the first buffer layer 110 and the first emitter layer 120, there is further a very thin GaAs interfacial layer which is not intentionally doped or has a doping concentration close to the intrinsic doping concentration. This approach is known to those skilled in the art and thus the GaAs interfacial layer is not intentionally shown in the embodiment of FIG. 1.

Above the first emitter layer 120 is the first window layer 130 which works to reduce the recombination loss of minority carriers. If the material of the first emitter layer 120 is n-type GaAs, the material of the window layer 130 is lattice-matched n-type GaInP, and the n-type doping concentration is between 5×10¹⁷ cm⁻³ and 5×10¹⁸ cm⁻³. If the first emitter layer 120 is made of n-type GaInP, the first window layer 130 is made of lattice-matched n-type GaInP whose doping concentration is at least 1 to 3 times higher than that of the first emitter layer 120, or lattice-matched n-type AlInP with doping concentration between 5×10¹⁷ cm⁻³ and 5×10¹⁸ cm⁻³.

Above the first window layer 130 is an n+-type first tunnel diode layer 140 made of lattice-matched n+-type GaInP with an n+-type doping concentration of at least 1×10¹⁹ cm⁻³.

Above the n+-type first tunnel diode layer 140 is a p+-type first tunnel diode layer 150 made of p+-type AlGaAs with a p+-type doping concentration of at least 1×10¹⁹ cm⁻³. The n+-type first tunnel diode layer 140 and the p+-type first tunnel diode layer 150 constitute a first tunnel diode layer 151 which can electrically connect the upper and lower adjacent sub-cells in series.

Above the p+-type first tunneling diode layer 150 is the second back surface field layer 160 which works to keep minority carriers away from the interface between the base layer and the back surface field layer and reduce recombination loss. The material of the second back surface field layer 160 is lattice-matched p-type AlGaInP, and the p-type doping concentration is between 5×10¹⁷ cm⁻³ and 5×10¹⁸ cm⁻³. The second back surface field layer 160 has a first surface 161 and a second surface 162 at the opposite site, wherein the second surface 162 is adjacent to the p+-type first tunnel diode layer 150.

Above the first surface 161 of the second back surface field layer 160 is the second base layer 170 whose material is lattice-matched p-type GaInP, with the energy gap about 1.9 eV. The p-type doping concentration is between 1×10¹⁶ cm⁻³ and 1×10¹⁸ cm⁻³.

Above the second base layer 170 is the second emitter layer 180 whose material is lattice-matched n-type GaInP, and the n-type doping concentration is between 5×10¹⁷ cm⁻³ and 5×10¹⁸ cm⁻³. In another embodiment, between the second base layer 170 and the second emitter layer 180, there is further a very thin GaInP interfacial layer which is not intentionally doped or has a doping concentration close to the intrinsic doping concentration. This approach is known to those skilled in the art and thus the GaInP interfacial layer is not intentionally shown in the embodiment of FIG. 1.

Above the second emitter layer 180 is the second window layer 190 which works to reduce the recombination loss of minority carriers. The material of the second window layer 190 is lattice-matched n-type AlInP, and the n-type doping concentration is between 5×10¹⁷ cm⁻³ and 5×10¹⁸ cm⁻³.

Above the second window layer 190 is the first contact layer 200 whose function is to guide the current generated by lighting to the battery to the external circuit for use. The material of the first contact layer 200 is n+-type GaAs, and the n+ type doping concentration is at least 1×10¹⁹ cm⁻³.

Above the first contact layer 200 is an etch stop layer 210 made of lattice-matched GaInP.

In order to protect the GaInP (energy gap 1.9 eV) second sub-cell structure from roughening caused by the desorption of surface atom due to the lack of V-group airflow protection in the process environment when the substrate 100 is turned over for the third sub-cell (energy gap 1.0 eV) film growth in the subsequent process, therefore, in this embodiment, a cover layer 220 is formed on the etch stop layer 210.

Next, the epi wafer is taken out from the reaction chamber, and if necessary, perform wet etching to remove the epitaxial damage layer on the second surface 102 of the GaAs substrate 100. Then the wafer is turned over, and a second buffer layer 230 is grown on the second surface 102 of the GaAs substrate 100. The material of the buffer layer 230 is GaAs, and the buffer layer 230 also serves as a part of the base layer. Likewise, if the original doping concentration of the GaAs substrate 100 is higher than 1×10¹⁸ cm⁻³, the p-type doping concentration of the second buffer layer 230 should be equal to or higher than 1×10¹⁸ cm⁻³.

Above the second buffer layer 230 is the first back surface field layer 240 which works to keep minority carriers away from the interface between the base layer and the back surface field layer and reduce recombination loss. The material of the first back surface field layer 240 is lattice-matched p-type GaInP or p-type AlGaAs, and the p-type doping concentration is between 5×10¹⁷ cm⁻³ and 5×10¹⁸ cm⁻³.

Above the first back surface field layer 240 is a p+-type second tunnel diode layer 250 made of lattice-matched p+-type AlGaAs or p+-type GaAs, and the p+-type doping concentration is at least 1×10¹⁹ cm⁻³.

Above the p+-type second tunnel diode layer 250 is an n+-type second tunnel diode layer 260 made of lattice-matched n+-type GaInP or n+-type GaAs, and the n+-type doping concentration of at least 1×10¹⁹ cm⁻³. The p+-type second tunnel diode layer 250 and the n+-type second tunnel diode layer 260 constitute a second tunnel diode layer 261 which can electrically connect the upper and lower adjacent sub-cells in series.

Above the n+-type second tunnel diode layer 260 is a graded buffer layer 270 which can gradually change the lattice constant from the originally lattice-matched with the substrate 100 to the lattice constant of the third sub-cell. By optimizing the epitaxial parameters of the graded buffer layer 270, the density of dislocation defects generated during the lattice gradient process can be minimized. The material of the graded buffer layer 270 is n-type GaInP or n-type AlInAs, and the n-type doping concentration is between 5×10¹⁷ cm⁻³ and 5×10¹⁸ cm⁻³. The change of the ratio of the n-type GaInP or n-type AlInAs composition elements along the thickness direction can be linear gradient, stepped gradient, or a combination of the two. Since the energy gap of the material GaInP or AlInAs of the graded buffer layer 270 is higher than that of the GaAs substrate, the graded buffer layer 270 will not absorb incident light with an energy lower than 1.4 eV, which can ensure that the incident light energy can be effectively absorbed by the base layer of the third sub-cell and converted into current.

Above the graded buffer layer 270 is the third window layer 280 which works to reduce the recombination loss of minority carriers. The material of the third window layer 280 is n-type GaInP whose lattice constant matches that of the third sub-cell InGaAs (1.0 eV), and thus it is significantly different from the lattice constant of the aforementioned lattice-matched GaInP material. The n-type doping concentration of the third window layer 280 is between 5×10¹⁷ cm⁻³ and 5×10¹⁸ cm⁻³.

Above the third window layer 280 is the third emitter layer 290 made of n-type InGaAs with an indium content of 20-40%. In another embodiment, the indium content is 30% (i.e. In_{0.3}Ga_{0.7}As, the energy gap is about 1.0 eV). The n-type doping concentration of the third emitter layer 290 is between 5×10¹⁷ cm⁻³ and 5×10¹⁸ cm⁻³

Above the third emitter layer 290 is the third base layer 300 made of p-type InGaAs with an indium content of 20-40%. In another embodiment, the indium content is 30% (i.e. In_{0.3}Ga_{0.7}As, the energy gap is about 1.0 eV). The p-type doping concentration of the third base layer 300 is between 1×10¹⁶ cm⁻³ and 1×10¹⁸ cm⁻³. In another embodiment, between the third emitter layer 290 and the third base layer 300, there is further a very thin InGaAs interface layer which is not intentionally doped or has a doping concentration close to the intrinsic doping concentration. This approach is known to those skilled in the art and thus the InGaAs interfacial layer is not intentionally shown in the embodiment of FIG. 1.

Above the third base layer 300 is the third back surface field layer 310 which works to keep minority carriers away from the interface between the base layer and the back surface field layer and reduce recombination loss. The material of the third back surface field layer 310 is p-type GaInP whose lattice constant matches that of the third sub-cell InGaAs (1.0 eV), and thus it is significantly different from the lattice constant of the aforementioned lattice-matched GaInP material. The p-type doping concentration of the third back surface field layer 310 is between 5×10¹⁷ cm⁻³ and 5×10¹⁸ cm⁻³.

Above the third back surface field layer 310 is the second contact layer 320 whose function is to guide the current generated by lighting to the battery to the external circuit for use. The material of the second contact layer 320 is p+-type InGaAs, and the content of indium is 20-40%. In another embodiment, the content of indium is 30% (i.e. In_{0.3}Ga_{0.7}As, the energy gap is about 1.0 eV). The p+-type doping concentration of the second contact layer 320 is at least 1×10¹⁹ cm⁻³.

After a series of thin film growth processes described above, a triple-junction solar cell structure with a upright structure as shown in FIG. 1 can be obtained. The instant disclosure is not limited to the triple-junction solar cells, those skilled in the art should be able to understand and have the ability to further extend the concept of the instant disclosure regarding to structure of three-junction solar cells, and make a four-junction solar cells or a multi junction solar cell. For example, between the third sub-cell of the InGaAs bottom layer and the second contact layer, those skilled in the art can use the concept of the instant disclosure to further add a third tunnel diode layer, a second graded buffer layer, and a fourth sub-cell with an energy gap of 0.7 eV in order to accomplish a four-junction solar cell.

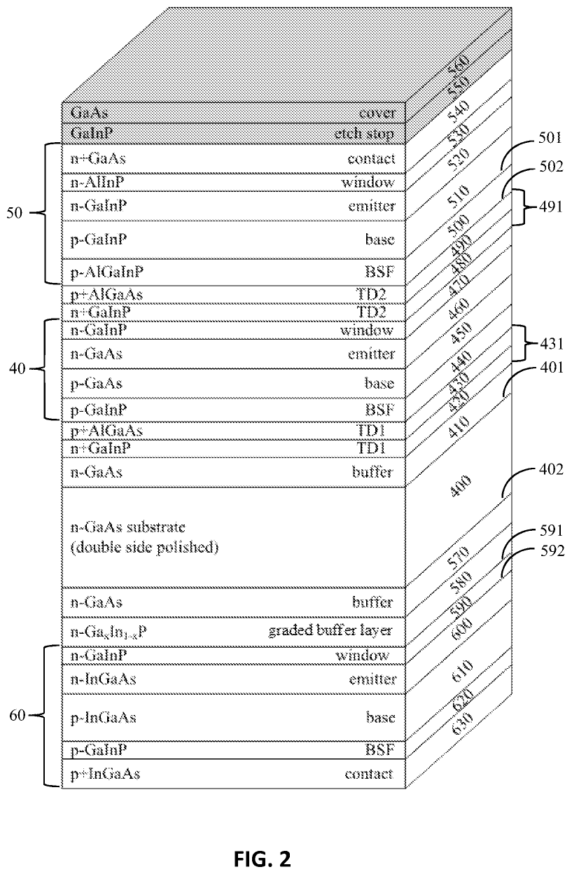

Please refer to FIG. 2, which is a structural diagram of a multi junction solar cell according to another embodiment of the instant disclosure. The implementation of the instant disclosure will be described in detail according to the structural diagram. The substrate used in this embodiment is a double-sided polished n-type GaAs substrate 400, the thickness of which is not more than 200 microns, and in this embodiment, the double-sided polished n-type GaAs substrate 400 itself does not serve as a light-absorbing base layer.

At first, a first buffer layer 410 is grown on the first surface 401 of the GaAs substrate 400. The material of the first buffer layer 410 is n-type GaAs, and the n-type doping concentration is between 1×10¹⁸ cm⁻³ and 1×10¹⁹ cm⁻³.

Above the first buffer layer 410 is an n+-type first tunnel diode layer 420 made of lattice-matched n+-type GaInP or n+-type GaAs with an n+-type doping concentration of at least 1×10¹⁹ cm⁻³.

Above the n+-type first tunnel diode layer 420 is a p+-type first tunnel diode layer 430 made of p+-type AlGaAs or p+-type GaAs with a p+-type doping concentration of at least 1×10¹⁹ cm⁻³. The n+-type first tunnel diode layer 420 and the p+-type first tunnel diode layer 430 constitute a first tunneling diode layer 431 which can electrically connect the upper and lower adjacent sub-cells in series.

Above the p+ type first tunneling diode layer 430 is the first back surface field layer 440 which works to keep minority carriers away from the interface between the base layer and the back surface field layer and reduce recombination loss. The material of the first back surface field layer 440 is lattice-matched p-type GaInP or p-type AlGaAs, and the p-type doping concentration is between 5×10¹⁷ cm⁻³ and 5×10¹⁸ cm⁻³.

Above the first back surface field layer 440 is the first base layer 450 whose material is p-type GaAs with the energy gap about 1.4 eV. The p-type doping concentration is between 1×10¹⁶ cm⁻³ and 1×10¹⁸ cm⁻³.

Above the first base layer 450 is the first emitter layer 460 made of homojunction n-type GaAs, and the n-type doping concentration is between 5×10¹⁷ cm⁻³ and 5×10¹⁸ cm⁻³. In another embodiment, the material of the first emitter layer 460 can also be a lattice-matched heterojunction n-type GaInP, and the n-type doping concentration is between 5×10¹⁷ cm⁻³ and 5×10¹⁸ cm⁻³. In another embodiment, between the first base layer 450 and the first emitter layer 460, there is further a very thin GaAs interfacial layer which is not intentionally doped or has a doping concentration close to the intrinsic doping concentration. This approach is known to those skilled in the art and thus the GaAs interfacial layer is not intentionally shown in the embodiment of FIG. 2.

Above the first emitter layer 460 is the first window layer 470 which works to reduce the recombination loss of minority carriers. In one embodiment, when the material of the first emitter layer 460 is n-type GaAs, and the material of the first window layer 470 is lattice-matched n-type GaInP, the n-type doping concentration is between 5×10¹⁷ cm⁻³ and 5×10¹⁸ cm⁻³. In another embodiment, when the material of the first emitter layer 460 is lattice-matched n-type GaInP, the material of the first window layer 470 can be lattice-matched n-type GaInP with doping concentration at least 1-3 times higher than that of the first emitter layer 460, or the lattice-matched n-type AlInP with an n-type doping concentration between 5×10¹⁷ cm⁻³ and 5×10¹⁸ cm⁻³.

Above the first window layer 470 is an n+-type second tunnel diode layer 480 made of lattice-matched n+-type GaInP with an n+-type doping concentration of at least 1×10¹⁹ cm⁻³.

Above the n+-type second tunnel diode layer 480 is a p+-type second tunnel diode layer 490 made of p+-type AlGaAs with a p+-type doping concentration of at least 1×10¹⁹ cm⁻³. The n+-type second tunnel diode layer 480 and the p+-type second tunnel diode layer 490 constitute a second tunnel diode layer 491 which can electrically connect the upper and lower adjacent sub-cells in series.

Above the p+-type second tunnel diode layer 490 is the second back surface field layer 500 which works to keep minority carriers away from the interface between the base layer and the back surface field layer and reduce recombination losses. The material of the second back surface field layer 500 is lattice-matched p-type AlGaInP, and the p-type doping concentration is between 5×10¹⁷ cm⁻³ and 5×10¹⁸ cm⁻³. The second back surface field layer 500 has a first surface 501 and second surface 502 at the opposite site, wherein the second surface 520 is adjacent to the p+-type second tunnel diode layer 490.

Above the first surface 501 of the second back surface field layer 500 is the second base layer 510 whose material is lattice-matched p-type GaInP with energy gap about 1.9 eV. The p-type doping concentration is between 1×10¹⁶ cm⁻³ and 1×10¹⁸ cm⁻³.

Above the second base layer 510 is the second emitter layer 520, the material is lattice-matched n-type GaInP, and the n-type doping concentration is between 5×10¹⁷ cm⁻³ and 5×10¹⁸ cm⁻³. In another embodiment, between the second base layer 510 and the second emitter layer 520, there is further a very thin GaInP interfacial layer which is not intentionally doped or has a doping concentration close to the intrinsic doping concentration. This approach is known to those skilled in the art and thus the GaInP interfacial layer is not intentionally shown in the embodiment of FIG. 2.

Above the second emitter layer 520 is the second window layer 530 which works to reduce the recombination loss of minority carriers. The material of the second window layer 530 is lattice-matched n-type AlInP, and the n-type doping concentration is between 5×10¹⁷ cm⁻³ and 5×10¹⁸ cm⁻³.

Above the second window layer 530 is the first contact layer 540 whose function is to guide the current generated by lighting to the battery to the external circuit for use. The material of the first contact layer 540 is n+ type GaAs, and the n+ type doping concentration is at least 1×10¹⁹ cm⁻³.

Above the first contact layer 540 is an etch stop layer 550 made of lattice-matched GaInP.

In order to protect the GaInP (energy gap 1.9 eV) second sub-cell structure from roughening caused by the desorption of surface atom due to the lack of V-group airflow protection in the process environment when the substrate 400 is turned over for the third sub-cell (energy gap 1.0 eV) film growth in the subsequent process, therefore, in this embodiment, a cover layer 560 is formed on the etch stop layer 550.

Next, the epi wafer is taken out from the reaction chamber, and if necessary, perform wet etching to remove the epitaxial damage layer on the second surface 402 of the GaAs substrate 400. Then the wafer is turned over, and a second buffer layer 570 is grown on the second surface 402 of the GaAs substrate 400. The second buffer layer 570 is made of n-type GaAs, and the n-type doping concentration is between 1×10¹⁸ cm⁻³ and 1×10¹⁹ cm⁻³.

Above the second buffer layer 570 is a graded buffer layer 580 which can gradually change the lattice constant from the originally lattice-matched with the substrate 400 to the lattice constant of the third sub-cell. By optimizing the epitaxial parameters of the graded buffer layer 580, the density of dislocation defects generated during the lattice gradient process can be minimized. The material of the graded buffer layer 580 is n-type GaInP or n-type AlInAs, and the n-type doping concentration is between 5×10¹⁷ cm⁻³ and 5×10¹⁸ cm⁻³. The change of the ratio of the n-type GaInP or n-type AlInAs composition elements along the thickness direction can be linear gradient, stepped gradient, or a combination of the two. Since the energy gap of the material GaInP or AlInAs of the graded buffer layer 580 is higher than that of the GaAs substrate, the graded buffer layer 580 will not absorb incident light with an energy lower than 1.4 eV, which can ensure that the incident light energy can be effectively absorbed by the base layer of the third sub-cell and converted into current.

Above the graded buffer layer 580 is the third window layer 590 which works to reduce the recombination loss of minority carriers. The third window layer 590 is made of n-type GaInP whose lattice constant matches the third emitter layer of the third sub-cell InGaAs (1.0 eV), and thus it is significantly different from the lattice constant of the aforementioned lattice-matched GaInP material. The n-type doping concentration of the third window layer 590 is between 5×10¹⁷ cm⁻³ and 5×10¹⁸ cm⁻³. The third window layer has a first surface 591 and a second surface 592 at the opposite site, wherein the first surface 591 is adjacent to the graded buffer layer 580.

Above the second surface 592 of the third window layer 590 is the third emitter layer 600 made of n-type InGaAs with an indium content of 20-40%. In another embodiment, the indium content is 30% % (i.e. In_{0.3}Ga_{0.7}As, the energy gap is about 1.0 eV). The n-type doping concentration of the third emitter layer 600 is between 5×10¹⁷ cm⁻³ and 5×10¹⁸ cm⁻³.

Above the third emitter layer 600 is the third base layer 610 made of p-type InGaAs with an indium content of 20-40%. In another embodiment, the indium content is 30% (i.e. In_{0.3}Ga_{0.7}As, the energy gap is about 1.0 eV). The p-type doping concentration of the third base layer 610 is between 1×10¹⁶ cm⁻³ and 1×10¹⁸ cm⁻³. In another embodiment, between the third emitter layer 600 and the third base layer 610, there is further a very thin InGaAs interface layer which is not intentionally doped or has a doping concentration close to the intrinsic doping concentration. This approach is known to those skilled in the art and thus the InGaAs interfacial layer is not intentionally shown in the embodiment of FIG. 2.

Above the third base layer 610 is the third back surface field layer 620 which works to keep minority carriers away from the interface between the base layer and the back surface field layer and reduce recombination loss. The material of the third back surface field layer 620 is p-type GaInP whose lattice constant matches that of the third sub-cell InGaAs (1.0 eV), and thus it is significantly different from the lattice constant of the aforementioned lattice-matched GaInP material. The p-type doping concentration of the third back surface field layer 620 is between 5×10¹⁷ cm⁻³ and 5×10¹⁸ cm⁻³.

Above the third back electric field layer 620 is the second contact layer 630 whose function is to guide the current generated by lighting to the battery to the external circuit for use. The material of the second contact layer 630 is p+-type InGaAs, and the content of indium is 20-40%. In another embodiment, the content of indium is 30% (i.e. In_{0.3}Ga_{0.7}As, the energy gap is about 1.0 eV). The p+-type doping concentration of the second contact layer 630 is at least 1×10¹⁹ cm⁻³.

After a series of thin film growth processes described above, a triple-junction solar cell structure with a upright structure as shown in FIG. 2 can be obtained. The instant disclosure is not limited to the triple-junction solar cells, those skilled in the art should be able to understand and have the ability to further extend the concept of the instant disclosure regarding to structure of three-junction solar cells, and make a four-junction solar cells or a multi junction solar cells. For example, between the third sub-cell of the InGaAs bottom layer and the second contact layer, those skilled in the art can use the concept of the instant disclosure to further add a third tunnel diode layer, a second graded buffer layer, and a fourth sub-cell with an energy gap of 0.7 eV in order to accomplish a four-junction solar cell.

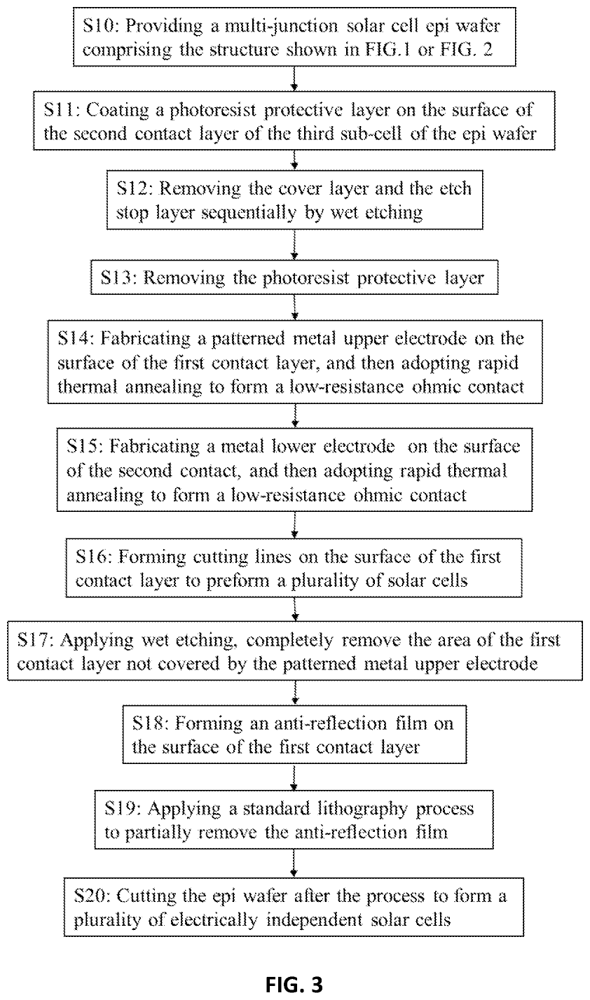

Please refer to FIG. 3, which is a schematic flow chart of the manufacturing method of the multi junction solar cell disclosed in the instant disclosure. The implementation of the manufacturing method of the instant disclosure is described in detail according to the schematic diagram. FIG. 3 shows a method for manufacturing a multi-junction solar cell including the structure of FIG. 1 or FIG. 2, which at least includes the following steps:
S10: According to the design of the multi junction solar cell structure in FIG. 1 or FIG. 2 of the disclosure, metalorganic chemical vapor deposition or other epitaxial methods are used to obtain a multi junction solar cell with a upright structure on a double-sided polished GaAs substrate.
S11: Coating a photoresist protective layer on the surface of the second contact layer of the third sub-cell (hereinafter referred to as the second contact layer) of the epi wafer to protect the thin film structure of the multi junction solar cell from damaged by etching in the subsequent step S12.
S12: Applying wet etching and selecting an appropriate etching solution to sequentially remove the cover layer and the etch stop layer.
S13: Removing the photoresist protective layer formed in step S11.
S14: Fabricating a patterned metal upper electrode on the surface of the first contact layer of the epi wafer by a standard photolithography process, and then adopting a rapid thermal annealing to form a low-resistance ohmic contact.
S15: Fabricating a lower metal electrode on the surface of the second contact layer by standard lithography process, and then adopting rapid thermal annealing to form a low-resistance ohmic contact.
S16: using a cutting machine or other mechanical means to form a plurality of cutting lines with a certain depth on the surface of the first contact layer, so as to preform a plurality of solar cells that are not fully electrically independent.
S17: Applying wet etching and selecting an appropriate etching solution, the first contact layer is partially removed, and eventually the first contact layer is completely removed in the area not covered by the metal upper electrode to expose the window layer below it, while the area covered by the metal upper electrode is still completely present. During the wet etching process, the lattice damage layer around the cutting line can be removed simultaneously.
S18: Forming an anti-reflection film on the surface of the first contact layer by using an electron gun evaporation machine or other evaporation equipment.
S19: Using a standard lithography process, partially remove the anti-reflection film above the patterned metal upper electrode on the surface of the first contact layer, and the area of the removed anti-reflection film is slightly larger than the electrode pins.
S20: Cutting completely along a plurality of cutting lines of a certain depth pre-formed on the surface of the first contact layer by a cutting machine or a laser cutting or other mechanical means to form a plurality of completely electrically independent solar cells.

The embodiments in the description are only used for illustration, not to limit the scope of the instant disclosure. Any equivalent modifications or changes carried out with regards to the multi junction solar cell structure and its manufacturing method of the instant embodiment should still be included within the scope of protection claimed by this disclosure.

In summary, the practical conversion efficiency of the mainstream product, GaInP (1.9 eV)/Ga(In)As (1.4 eV)/Ge (0.67 eV) triple-junction solar cell, on the market can reach ˜30%. However, this energy gap combination is not optimal for the solar spectrum AM0. To replace the Ge (0.67 eV) bottom sub-cell with a sub-cell having an energy gap of 1.0 eV, manufacturers use IMM technology to produce GaInP (1.9 eV)/Ga(In)As (1.4 eV)/In_{0.3}Ga_{0.7}As (1.0 eV) triple-junction solar cells. However, the IMM epitaxial methodology makes the cell structure grow upside down, the original epi substrate must be grinded/etched and removed, and the multi junction solar cell thin film structure is transferred to a carrier in conjunction with the device process. The IMM method used in manufacturing process is complicated and time-consuming. Besides, it is also difficult to obtain a good process yield. On the other hand, it has been reported in the prior art that the substrate double-sided growth technology is used to fabricate multi junction solar cells with a upright structure. Although the substrate double-sided growth technology does not involve the removal of the original epitaxial substrate and the transfer of the thin film structure to the carrier, and the device manufacturing process is relatively simple and can maintain a good process yield, most of them use dilute nitrogen arsenide GaInNAs to make sub-cells with an energy gap 1.0 eV. Thus, because of the high intrinsic carrier concentration of the GaInNAs material, the minority carrier lifetime is too short, and it is difficult to improve the overall conversion efficiency of the cell. To solve the above-mentioned problems, this disclosure adopts the substrate double-sided growth technology, using a double-sided polished GaAs substrate. After the GaAs (1.4 eV) first sub-cell, disposed at the middle layer of the cell, and the GaInP (1.9 eV) second sub-cell, disposed at the upper layer of the cell, are sequentially grown on the first surface of the substrate, the InGaAs (1.0 eV) third sub-cell, disposed at the bottom of the cell, is then grown on the second surface of the substrate, and eventually a triple-junction solar cell with a upright structure is obtained. The instant disclosure is not limited to triple-junction solar cells, it can be extended to multi junction solar cells by applying the concept of the instant disclosure. To compare the structure and manufacturing method of the existing multi-junction solar cell with the upright triple-junction solar cell disclosed in this disclosure, it only involves one graded buffer layer in the instant disclosure and therefore, only the third sub-cell at the bottom of InGaAs will have dislocation defects, and the other sub-cells are well lattice-matched and good epitaxy quality of them can thus be assured. In addition, the manufacturing method of the instant disclosure does not involve the removal of the original epitaxial substrate and the transfer of the thin film structure to the carrier, so the manufacturing process is relatively simple and can maintain a better process yield. The multi junction solar cell structure and the manufacturing method thereof according to the embodiments of the instant disclosure have distinct advantages.

The above embodiments are exemplary only, not limiting. Any other equivalent modifications or changes without departing from the spirit and scope of the instant disclosure should be included in the appended patent application scope.

What is claimed is:

1. A multi junction solar cell structure, comprising:
a first sub-cell having a first surface and a second surface opposite thereto;
a first tunnel diode layer disposed on the first surface of the first sub-cell;
a second sub-cell disposed on the first tunnel diode layer;
a second tunnel diode layer disposed on the second surface of the first sub-cell;
a graded buffer layer disposed on the second tunnel diode layer; and
a third sub-cell disposed on the graded buffer layer.

2. The solar cell structure according to claim 1, wherein the first sub-cell comprises:
a double-sided polished p-type GaAs substrate used as a light-absorbing base layer, and having a first surface and a second surface opposite thereto;
a first buffer layer disposed on the first surface of the p-type GaAs substrate;
a first emitter layer disposed on the first buffer layer;
a first window layer disposed on the first emitter layer, wherein the first window layer is adjacent to the first tunnel diode layer;
a second buffer layer disposed on the second surface of the p-type GaAs substrate; and
a first back surface field layer made of p-type GaInP or p-type AlGaAs, disposed on the second buffer layer, wherein the first back electric field layer is adjacent to the second tunnel diode layer.

3. The solar cell structure according to claim 2, wherein the second sub-cell comprises:
a second back surface field layer made of p-type AlGaInP, and having a first surface and a second surface opposite thereto, wherein the second surface of the second back surface field layer is adjacent to the first tunneling diode;
a second base layer disposed on the first surface of the second back surface field layer;
a second emitter layer disposed on the second base layer;
a second window layer disposed on the second emitter layer; and
a first contact layer disposed on the second window layer.

4. The solar cell structure according to claim 3, wherein the third sub-cell comprises:
a third window layer having a first surface and a second surface opposite thereto, wherein the first surface of the third window layer is adjacent to the graded buffer layer;
a third emitter layer disposed on the second surface of the third window layer;
a third base layer disposed on the third emitter layer;
a third back electric field layer disposed on the third base layer; and
a second contact layer disposed on the third back electric field layer.

5. The solar cell structure according to claim 4, wherein the first tunnel diode layer further comprises:
a p+-type first tunnel diode layer made of p+-type AlGaAs; and
an n+-type first tunnel diode layer made of n+-type GaInP, wherein the p+ type first tunnel diode layer is adjacent to the second back surface field layer of the second sub-cell, and the n+ type first tunnel diode layer is adjacent to the first window layer of the first sub-cell.

6. The solar cell structure according to claim 5, wherein the second tunnel diode layer further comprises:
a p+-type second tunnel diode layer made of p+-type AlGaAs or p+-type GaAs;
an n+-type second tunnel diode layer made of n+-type GaInP or n+-type GaAs, wherein the p+-type second tunnel diode layer is adjacent to the first back surface field layer of the first sub-cell, and the n+-type second tunnel diode layer is adjacent to the graded buffer layer.

7. The solar cell structure according to claim 6, wherein a material of the first emitter layer is n-type GaAs and a material of the first window layer is n-type GaInP, or the material of the first emitter layer is n-type GaInP and the material of the first window layer is n-type GaInP with 1-3 times higher doping concentration than that of the first emitter layer, or n-type AlInP.

8. The solar cell structure according to claim 7, wherein a material of the graded buffer layer can be n-type GaInP or n-type AlInAs, and a change of a ratio of component elements thereof along a thickness direction can be linear gradient, stepped gradient, or a combination of the two.

9. The solar cell structure according to claim 7, wherein a material of the third emitter layer is n-type InGaAs, and an indium content of the third emitter layer is between 20-40%, wherein a material of the third base layer is p-type InGaAs, and an indium content of the third base layer is between 20-40%.

10. A multi junction solar cell structure, comprising:
a double-sided polished n-type GaAs substrate having a first surface and an opposite second surface;
a first buffer layer disposed on the first surface of the n-type GaAs substrate;
a first tunnel diode layer disposed on the first buffer layer;
a first sub-cell disposed on the first tunnel diode layer;
a second tunnel diode layer disposed on the first sub-cell;
a second sub-cell disposed on the second tunnel diode layer;
a second buffer layer disposed on the second surface of the n-type GaAs substrate;
a graded buffer layer disposed on the second buffer layer; and
a third sub-cell disposed on the graded buffer layer.

11. The solar cell structure according to claim 10, wherein the first sub-cell comprises:
a first back surface field layer made of p-type GaInP or p-type AlGaAs, having a first surface and a second surface opposite thereto, wherein the second surface of the first back surface field layer is adjacent to the first tunnel diode layer;
a first base layer disposed on the first surface of the first back surface field layer;
a first emitter layer disposed on the first base layer; and
a first window layer disposed on the first emitter layer, wherein the first window layer is adjacent to the second tunnel diode.

12. The solar cell structure according to claim 11, wherein the second sub-cell comprises:
a second back surface field layer made of p-type AlGaInP, having a first surface and a second surface opposite thereto, wherein the second surface of the second back surface field layer is adjacent to the second tunnel diode layer;
a second base layer disposed on the first surface of the second back surface field layer;
a second emitter layer disposed on the second base layer;
a second window layer disposed on the second emitter layer; and
a first contact layer disposed on the second window layer.

13. The solar cell structure according to claim 12, wherein the third sub-cell comprises:
a third window layer having a first surface and a second surface opposite thereto, wherein the first surface of the third window layer is adjacent to the graded buffer layer;
a third emitter layer disposed on the second surface of the third window layer;
a third base layer disposed on the third emitter layer;
a third back surface field layer disposed on the third base layer; and
a second contact layer disposed on the third back electric field layer.

14. The solar cell structure according to claim 13, wherein the first tunnel diode layer further comprises:
a p+-type first tunnel diode layer made of p+-type AlGaAs or p+-type GaAs;
an n+-type first tunnel diode layer made of n+-type GaInP or n+-type GaAs, wherein the p+ type first tunnel diode layer is adjacent to the second surface of the first back surface field layer of the first sub-cell, and the n+ type first tunnel diode layer is adjacent to the first buffer layer.

15. The solar cell structure according to claim 14, wherein a material of the first emitter layer is n-type GaAs and a material of the first window layer is n-type GaInP, or the material of the first emitter layer is n-type GaInP and the material of the first window layer is the n-type GaInP with 1-3 time higher doping concentration than that of the first emitter layer, or n-type AlInP.

16. The solar cell structure according to claim 15, wherein a material layer of the graded buffer layer is n-type GaInP or n-type AlInAs, and a change of a ratio of composition elements thereof along a thickness direction can be linear gradient, stepped gradient, or a combination of the two.

17. The solar cell structure according to claim 15, wherein a material of the third emitter layer is n-type InGaAs, and an indium content of the third emitter layer is between 20-40%, wherein a material of the third base layer is p-type InGaAs, and an indium content of the third base layer is between 20-40%.

18. A method of manufacturing a multi junction solar cell of claim 9, comprising the following steps:
provide a multi junction solar cell epi wafer comprising a structure of claim 9;
coating a photoresist protective layer on the surface of the second contact layer of the third sub-cell of the multi junction solar cell epi wafer;
removing a cover layer and an etch stop layer on the second sub-cell sequentially by a wet etching;
removing the photoresist protective layer;
fabricating a patterned metal upper electrode on a surface of the first contact layer by a standard lithography process, and then adopting a rapid thermal annealing to form a low-resistance ohmic contact;
fabricating a lower metal electrode on a surface of the second contact layer by a standard lithography process, and then adopting the rapid thermal annealing to form the low-resistance ohmic contact;
applying the wet etching to completely remove an area of the first contact layer not covered by the patterned metal upper electrode to expose a window layer beneath, wherein an area of the first contact layer covered by the patterned metal upper electrode remains intact; and
cutting the multi junction solar cell epi wafer to form a plurality of electrically independent solar cells.

19. A method of manufacturing a multi junction solar cell of claim 17, comprising the following steps:
provide a multi junction solar cell epi wafer comprising a structure of claim 17;
coating a photoresist protective layer on a surface of the second contact layer of the third sub-cell of the multi junction solar cell epi wafer;
removing a cover layer and an etch stop layer on the second sub-cell sequentially by a wet etching;
removing the photoresist protective layer;
fabricating a patterned metal upper electrode on a surface of the first contact layer by a standard lithography process, and then adopting a rapid thermal annealing to form a low-resistance ohmic contact;
fabricating a lower metal electrode on a surface of the second contact layer by a standard lithography process, and then adopting the rapid thermal annealing to form the low-resistance ohmic contact;
applying the wet etching to completely remove an area of the first contact layer not covered by the patterned metal upper to expose the window layer beneath, wherein the area of the first contact layer covered by the patterned metal upper electrode remains intact; and
cutting the multi junction solar cell epi wafer to form a plurality of electrically independent solar cells.
